(19) United States
(12) Patent Application Publication
(10) Pub. No.: US 2016/0043272 A1
(43) Pub. Date: Feb. 11, 2016

(54) MONOLITHIC LIGHT-EMITTING DEVICE

(71) Applicant: CENTRE NATIONAL DE LA RECHERCHE SCIENTIFIQUE, Paris (FR)

(72) Inventors: Benjamin DAMILANO, NICE (FR); Hyonju KIM-CHAUVEAU, MOUGINS (FR); Eric FRAYSSINET, MOUANS SARTOUX (FR); Julien BRAULT, ANTIBES (FR); Philippe DE MIERRY, VALBONNE (FR); Sébastien CHENOT, MOUGINS (FR); Jean MASSIES, VALBONNE (FR)

(21) Appl. No.: 14/775,592

(22) PCT Filed: Mar. 12, 2014
(86) PCT No.: PCT/EP2014/054873

§ 371 Date: Sep. 11, 2015

(30) Foreign Application Priority Data
Mar. 14, 2013 (FR) 1352303

(51) Int. Cl. H01L 33/06; H01L 33/32; H01L 33/00

(52) U.S. Cl. CPC H01L 33/06; H01L 33/0075; H01L 33/325; H01L 2933/0033; H01L 2933/0016

(57) ABSTRACT

A Light-emitting device comprises a monolithic matrix of III-nitride elements, the matrix comprising at least one first stack of quantum wells or of planes of quantum dots able to emit photons at at least one second wavelength by optical pumping by the photons emitted by the first stack, and a region separating the two stacks, and first and second electrodes arranged to allow an electrical current to pass through the stacks, the second stack is n-doped, the separating region comprises a tunnel junction having an n⁺⁺-doped region arranged on the same side as the second stack and a p⁺⁺-doped region arranged on the opposite side and the first stack is arranged between separating region and at least one n-doped layer. Method for manufacturing such device.

The invention relates to a light-emitting device, more particularly to a light-emitting diode and notably to a white light-emitting diode. The device of the invention in particular comprises a monolithic matrix, preferably produced by epitaxial growth, of group-III nitrides, using (Al,Ga,In)N alloys for example.

The invention also relates to a method for manufacturing such a device.

Prior-art monolithic white diodes comprise a plurality of light-emitting regions, formed by quantum wells or planes of quantum dots made of group-III nitrides, emitting at different wavelengths that combine to give white light. See for example U.S. Pat. No. 6,445,009.

However, the light-emission efficiency of these devices is limited by that of the light-emitting regions of lowest efficiency, notably those emitting in the yellow. Furthermore, the distribution of electrons and holes in the quantum dots or quantum wells is modified depending on the voltage applied to the diode. The color of the light emitted may therefore vary with electric current density.

To avoid these drawbacks, it is known to produce white light-emitting diodes comprising a light-emitting region emitting blue or ultraviolet light, and a fluorescent region, pumped by said blue or ultraviolet light and re-emitting radiation at a longer wavelength. Conventionally, diodes of this type are not monolithic: for example, in the case of document US 2006/0124917 the fluorescent region consists of a stack of quantum wells made of II-VI semiconductors added to a blue light-emitting diode made of III-V semiconductors. The separate production of the blue light-emitting diode and the fluorescent region, then their assembly, makes the fabrication of such a device complex and expensive.

Document US 2003/006430 describes a monolithic white light-emitting diode comprising a light-emitting region and a fluorescent region consisting of layers of Si- or Se-doped GaN having a yellow emission in caused by deep energy levels that are due to crystal defects. The fluorescent emission thus obtained has a limited quantum efficiency, and its wavelength cannot be adjusted to obtain light having a desired hue.

Documents US 2004/0227144 and WO 2007/104884 describe monolithic white diodes comprising an active portion (light-emitting diode), through which an electric current may be made to flow, and a passive portion (wavelength converter), through which, because of its position, the electric current is unable to flow. The active portion comprises a first stack of quantum wells (or planes of quantum dots) made of III-V semiconductors, emitting blue radiation via electrical injection of said electric current, whereas the passive portion comprises a second stack of quantum wells (or planes of quantum dots) made of III-V semiconductors, emitting yellow or green and red radiation via optical pumping by the radiation emitted by the first stack.

Such a structure is advantageous but difficult to produce. Specifically, in order to prevent the electric current that flows through the active portion from flowing through the passive portion, the latter must be produced first, by epitaxial deposition on a suitable substrate. The active portion must be produced subsequently, above said passive portion. However, in order to be able to operate correctly as a wavelength converter, the stack of quantum wells or planes of quantum dots of the passive portion must have a high indium (In) content—typically higher than 20%—thereby making it unstable at temperatures above about 1050° C. This means that the active portion must be grown at “low” temperatures (less than 1000° C. and preferably 950° C. or less), thereby precluding use of metal organic chemical vapor deposition (MOCVD) techniques, which are the most commonly employed in the industry. It is interesting to note that the aforementioned document US 2004/0227144 describes a fabrication method comprising a step of growing the active portion at a temperature of 1020-1040° C. that, on account of the time required to produce it, would necessarily lead to degradation (and notably blackening) of the converter in the passive portion.

Document DE 10 2004 052 245 describes a light-emitting diode comprising an active (light-emitting) portion and a passive portion (wavelength converter) produced above the active portion. This “inverted” structure makes it possible to produce the passive portion after the active portion, and therefore to avoid any risk of thermal degradation. However, this implies passing the electric current through the passive portion, which is unconventional and could in principle degrade the electrical properties of the device, or even induce undesired light emission from the wavelength converter.

The invention aims to mitigate the aforementioned drawbacks of the prior art, and notably to provide a monolithic light-emitting semiconductor device having a high efficacy, an emission spectrum that is stable over time, and good electrical properties, and that may be fabricated using standard industrial processes.

One subject of the invention, allowing such an aim to be achieved, consists of a device according to claim 1.

Another subject of the invention is a method according to claim 6, allowing such a device to be fabricated.

The dependent claims relate to advantageous embodiments of such a device and such a method.

Other features, details and advantages of the invention will become apparent on reading the description given with reference to the appended drawings, which are given by way of example and show, respectively:

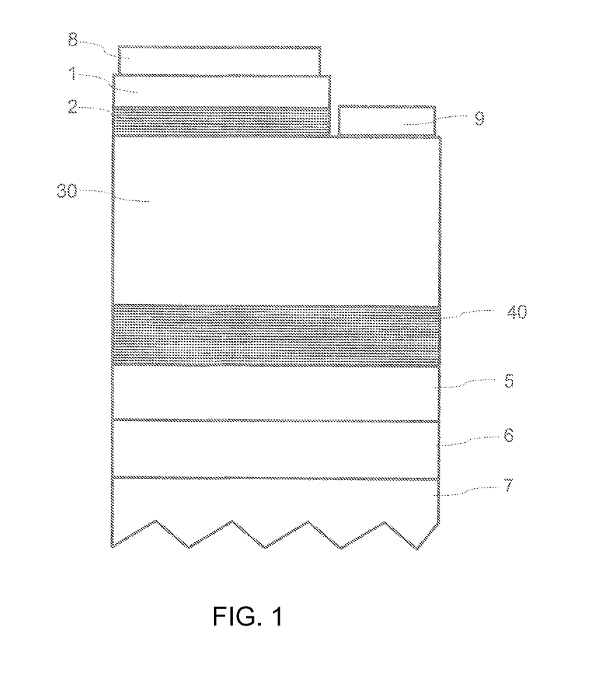

FIG. 1, the structure of a prior-art monolithic white light-emitting diode made of group-III nitrides;

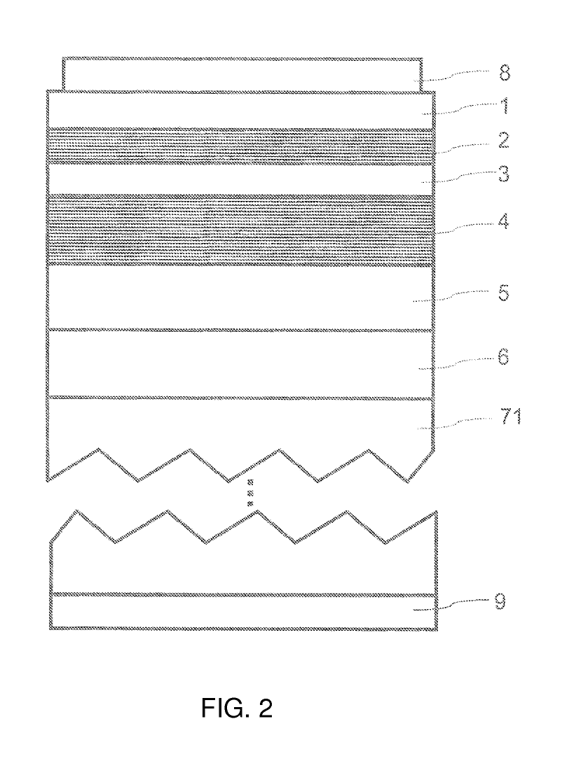

FIGS. 2 to 7, structures of white light-emitting diodes given by way of example and not according to the invention;

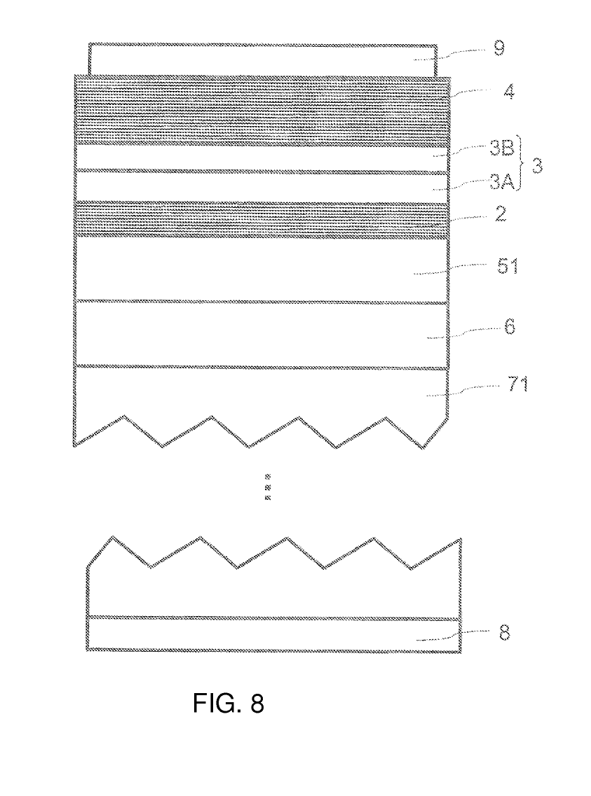

FIG. 8, the structure of a white light-emitting diode according to one embodiment of the invention;

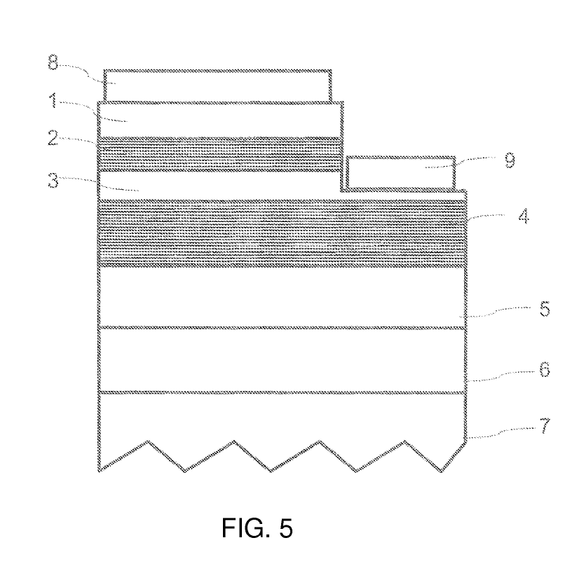

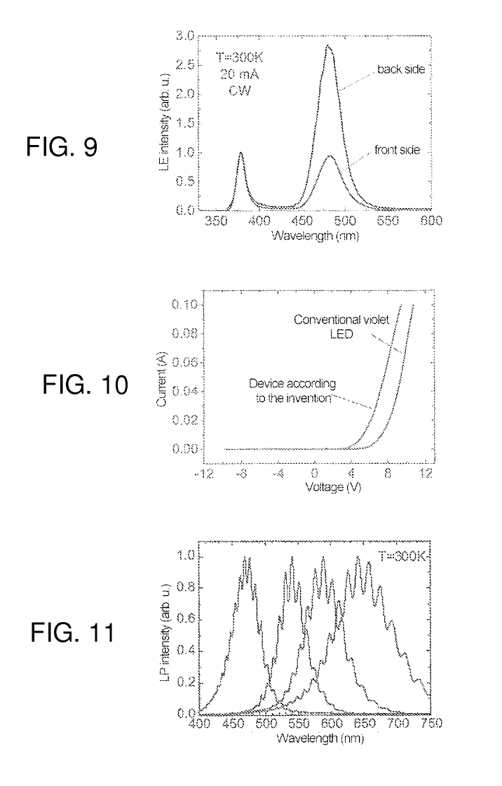

FIG. 9, the emission spectrum of a monolithic white light-emitting diode made of group-III nitrides and of the type in FIG. 5, acquired on the front side (i.e. the side opposite the substrate) and on the back side (i.e. through the substrate);

FIG. 10, the voltage-current characteristics of said monolithic white light-emitting diode made of group-III nitrides, compared to those of a conventional blue diode; and

FIG. 11, the normalized photoluminescence spectra of three wavelength converters that are usable, separately or conjointly, in a monolithic white light-emitting diode made of group-III nitrides according to one embodiment of the invention.

FIG. 1 illustrates the structure of a monolithic white diode known from the prior art and particularly from the aforementioned document WO 2007/104884. Such a diode comprises, from bottom to top:

a substrate 7 that is transparent to the light that must be emitted by the device and for example made of sapphire, SiC, ZnO or GaN;

one or more buffer layers 6 made of intrinsic AlGaInN or, more precisely, non intentionally doped (n.i.d) AlGaInN; “AlGaInN” is here a general formula that means AlₓGa_{y}In_{z}N, where x+y+z=1 and where one or two of the stoichiometric coefficients x, y, z may also be zero;

a layer 5, referred to as the “lower” layer, made of u.i.d AlGaInN; a “converter” formed by a stack 40 of quantum wells or planes of quantum dots made of InₓGa₁₋ₓN/GaN, which are capable of absorbing radiation at a first wavelength (typically in the blue) and of re-emitting radiation at a second longer wavelength (typically in the yellow); the stoichiometric coefficient x is generally higher than or equal to 0.2;

a region (layer or multilayer structure) 30, referred to as the “separating region”, made of n-type AlGaInN and typically about 2 μm in thickness;

a stack 2 of quantum wells or planes of quantum dots made of InₓGa₁₋ₓN/GaN (typically where x<0.2) capable of emitting radiation at said first wavelength via electron injection; and

a region (layer or multilayer structure) 1, referred to as the “upper” region, made of p-type AlGaInN and typically about 200 nm in thickness (since p-type AlGaInN is very resistive, it is sought to minimize the thickness of this region).

The regions 1, 2, 30, 40, 5 and 6 form a monolithic matrix made of group-III nitride semiconductors, said matrix generally being fabricated by epitaxial deposition on the substrate 7. In the interior of this matrix, the regions 1, 2 and 30 form a light-emitting diode.

A “stair-step” etch allows a region of the upper surface of the region 30 to be exposed in order to allow an electrode 9 to be deposited thereon. Another electrode 8 is deposited on the upper layer 1 (its area must be larger than that of the electrode 9 because of the less favorable electrical properties of the p-type semiconductor. Preferably, the electrode 8 will completely cover the surface of the light-emitting diode in order to ensure uniform current injection). The electrodes 8 and 9 make it possible to flow an electric current through the diode 1-2-30; this is therefore referred to as the “active portion” of the matrix. In contrast, it will be understood that no current can pass through the layers 40, 5 and 6 (the “passive portion”) because of the presence of the undoped “separating” layer 30, which has a relatively large thickness.

As mentioned above, such a layer 3 must be deposited at a high temperature (higher than 1000° C.), thereby risking damage to the converter 40.

FIG. 2 shows a light-emitting diode not according to the invention, in which an electric current passes both through the “active” portion and through the “passive” portion (wavelength converter) of the matrix. The same reference numbers indicate the same elements as in FIG. 1.

Relative to the device in FIG. 1, the following differences will be noted:

the electrode 9 is produced on the back side of the substrate, which must be conductive (reference 71): thus a device having a vertical structure is produced and the “stair-step” etching step is avoided; the downside of this is that the electric current passes right through the device, including through the converter; this electrode may be transparent or semitransparent or take the form of a grid in order to allow photon extraction, whereas it is preferable for the electrode 8 on the “p” side of the device to be a thick metal layer in order to ensure a better electrical contact and to also behave as a reflector of light;

the converter—identified by the reference 4—is different from the converter 40 in FIG. 1 in that it is “n”-doped in order to have a sufficient conductivity (“p”-type doping is possible in theory but less advantageous);

the separating region—identified by the reference 3—may have a much smaller thickness, for example of about a few hundred nanometers, or even of only 100 nm or less. This is because there is no longer any need for it to isolate the converter, which in any case is passed through by the electric current. Furthermore, the converter 4, being doped, is able to carry out the function of injection of electrons into the “active” stack 2.

A layer 3 this thin may be grown by metal organic chemical vapor deposition at a temperature below 1000° C., for example of about 950° C. or less, thereby avoiding any risk of damaging the converter 4.

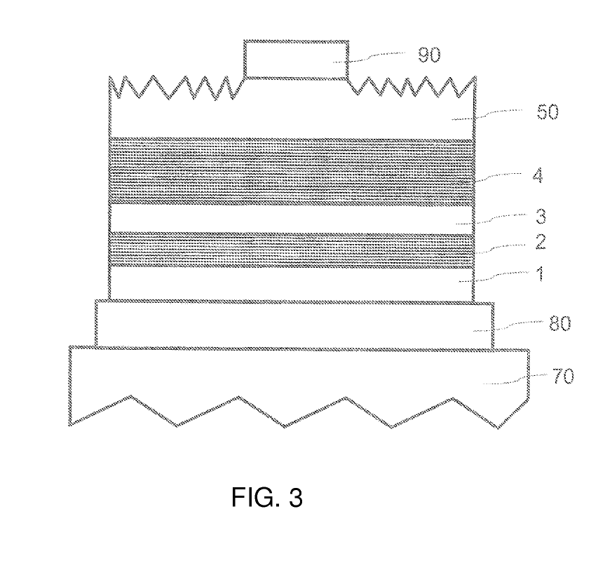

FIG. 3 illustrates a light-emitting diode not according to the invention, in which an electric current passes both through the “active” portion and through the “passive” portion (wavelength converter) of the matrix. This diode also has a vertical structure, but it is produced using a flip-chip technique. In other words, the epitaxial matrix is separated from its substrate, flipped and deposited on another substrate 70, which is not necessarily transparent. The reference 80 identifies a metal soldering layer that also serves as an electrode. The other electrode 90 is deposited on the n-type layer 50 (which corresponds to the “lower” layer 5 in FIGS. 1 and 2, but which now is located “at the top” of the device). The surface of said layer 50 may be textured in order to facilitate extraction of photons.

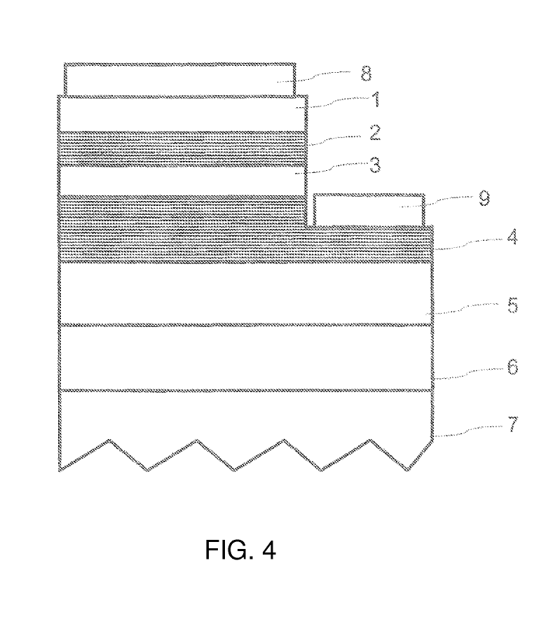

FIGS. 4, 5 and 6 relate to three light-emitting diodes not according to the invention, in which an electric current passes both through the “active” portion and through the “passive” portion (wavelength converter) of the matrix. These diodes have a structure closer to that in FIG. 1. The only differences relate to the thickness of the separating region 3, which is smaller (as in the case in FIGS. 2 and 3), and the fact that the converter 4 is doped and preferably n-doped. Because of the small thickness of the separating layer 3, lines of electric current pass through at least the upper portion of the converter 4.

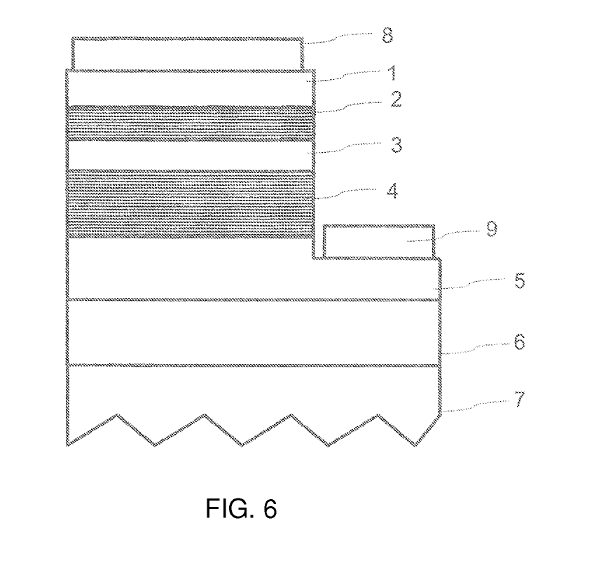

In the case in FIG. 4, the electrical contact 9 is produced on a lateral portion of the converter. In that in FIG. 5, said contact is produced on a lateral portion of the separating region 3. In the case in FIG. 6, this contact is produced on a lateral portion of the lower layer 5. These three variants are substantially equivalent; however, it will be noted that in order to make it possible to produce the contact on the separating region 3, it is necessary to control the “stair-step” etch very precisely because of the small thickness of this layer.

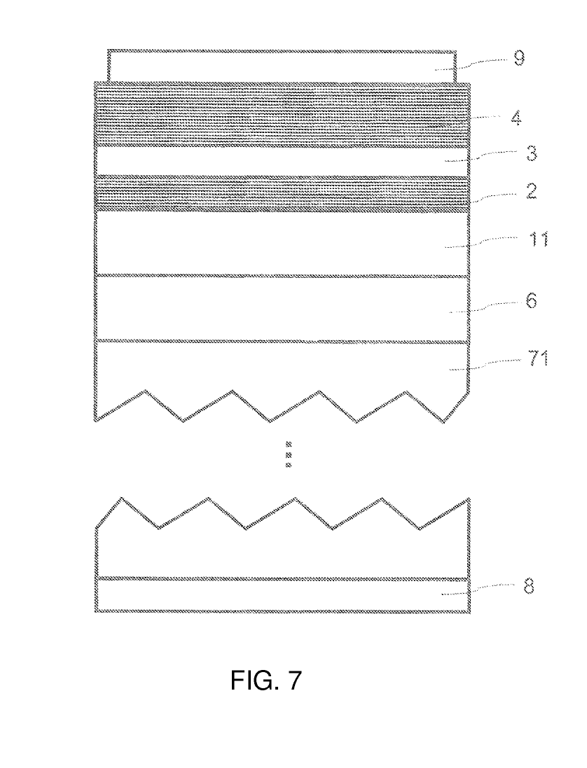

FIG. 7 illustrates the structure of another light-emitting diode that is based on a different principle to that behind the diodes described above. Specifically, in this case, the key to preventing thermal damage to the converter 4 does not lie so much in the production of a thin separating layer 3 as in the adoption of an inverted structure, in which said converter is produced after the “active” stack 2. As in the other examples, this implies the need to permit the passage of an electric current through said converter.

Thus, the device in FIG. 7 comprises, from bottom to top:

an electrode 8 (the structure is vertical);

a p-type conductive substrate 71;

a buffer layer 6 made of p-type AlGaInN;

a layer 11 made of p-type AlGaInN;

a light-emitting stack 2 of quantum wells or planes of quantum dots of III-V semiconductors;

an n-type or u.i.d separating region 3 the thickness of which is not critical;

an n-doped converter 4; and

an electrode 9, which may be deposited directly on the converter 4, or by way of an n-type contact layer (not shown). Preferably, the electrode 9 may be transparent or semitransparent or take the form of a grid in order to allow the generated radiation to be extracted.

The advantage of this device is that the converter 4 is produced last; it cannot therefore be damaged even if other layers are deposited (beforehand) at high temperatures.

The main drawback of this device resides in the fact that the current must pass through a substantial thickness of p-type semiconductor (substrate 71, layers 6 and 11) that has a high resistivity; furthermore, the contact 8 is made to a p-type region (the substrate 71), thereby further increasing the resistance seen by the current. To decrease this resistance a stair-step etch could be carried out in order to make a contact directly to a portion of the layer 11. However, because of the resistivity of said layer, this would lead to a not very uniform distribution of the current; furthermore, the etching operation would be liable to degrade the conductivity of the p-type layers, whereas this problem does not arise with n-type layers.

Similar problems arise in the case of the device illustrated in FIG. 2 of the aforementioned document DE 10 2004 052 245.

The structure in FIG. 8, which illustrates one embodiment of the invention, allows these drawbacks to be remedied. In this device, the p-type layer 11 is replaced by a less resistive n-type layer 51. On the downside, it is necessary to provide a p-type layer 3A on the opposite side of the active stack 2. However, as, in general, it is not desired to produce a p-doped converter 4, a tunnel junction 3B is inserted having its p⁺⁺ side on the side of the layer 3A and its n⁺⁺ side on the side of the converter 4, which is n-doped. The tunnel junction 3B has a very small thickness, of about a few nanometers, whereas the p-type layer 3A typically has a thickness of about 100 nm.

Only devices comprising an n-doped converter 4 have been described in detail. If the doping of the converter were p-type, that of the other layers of the matrix would have to change in consequence. However, it is known that p-type converters are less effective than n-type converters.

A single embodiment of the invention has been described; a plurality of other variants are however possible. In particular, devices according to the invention may have a more complex structure, comprising additional layers or replacing “single” layers with multilayer structures. In particular, a given device may comprise a plurality of converters emitting at various wavelengths.

The device in FIG. 8 is intended to emit white light, but this is not an essential feature of the invention.

The device in FIG. 8 comprises a conductive substrate (of n-type, just like the buffer layer 6), and an electrode 8 deposited on the back side (opposite that bearing the matrix) of this substrate. As a variant, the substrate could be insulating and the electrode 8 could make direct contact with the layer 51 by virtue of a stair-step etch (see FIG. 6). According to another variant, the matrix could be detached from the substrate and the electrode 8 could be deposited directly on the back side of the layer 51. These examples are nonlimiting. In any case, by virtue of the use of the tunnel junction 3B the thickness of the p-doped regions through which the current passes is minimized and it is possible to ensure that the electrical contacts are made to n-doped regions.

In order to make the invention, the inventors had to overcome a technical prejudice. Specifically, it was believed previously that the passage of an electric current through the converter 4 would have, on the one hand, disrupted the fluorescent emission of said converter, and, on the other hand, unacceptably degraded the electrical properties of the device. The present inventors realized that, unexpectedly, this is not the case.

This has been demonstrated experimentally by producing a prototype having the structure in FIG. 5. The matrix of this prototype was produced entirely by MOCVD. It comprises the following stack of layers, starting from the sapphire substrate 7: a lower layer 5 of 4.5 μm thickness made of Si-doped GaN, a converter 4 formed from 20 In_{0.25}Ga_{0.75}N (1.2 nm)/GaN:Si (20 nm) quantum wells, a separating layer 3 of GaN:Si (20 nm), a light-emitting stack 2 formed from 5 In_{0.1}Ga_{0.9}N (1.2 nm)/GaN (10 nm) quantum wells, and an upper layer (in fact, a multilayer structure) 1 comprising a 20 nm thickness of Al_{0.14}Ga_{0.86}N:Mg and 235 nm of GaN:Mg. The Si-doped layers have an n-type conductivity and the Mg-doped layers a p-type conductivity.

FIG. 9 shows the emission spectra of this prototype, supplied with a current of 20 mA at room temperature. Two spectra were acquired, a “front side” spectrum and a “back side” spectrum, i.e. a spectrum acquired through the substrate. A first peak at 380 nm (violet) corresponding to the emission of the active stack 2 and a second peak at 480 nm (yellow) corresponding to the fluorescence of the converter 4 may be seen. The two spectra were normalized to the intensity of the peak at 380 nm. It will be noted that the peak at 480 nm is more intense on the back side than on the front side. This is expected because the front-side emission also comprises 380 nm photons that have not passed through the converter.

FIG. 10 allows the current-voltage characteristics of the prototype to be compared with those of a conventional violet light-emitting diode (LED) produced under comparable growth conditions. It comprises the following stack of layers, starting from the sapphire substrate 7: a lower layer 5 of 4.5 μm thickness made of Si-doped GaN, a light-emitting stack 2 formed from 5 In_{0.1}Ga_{0.9}N (1.2 nm)/GaN (10 nm) quantum wells, and an upper layer (in fact, a multilayer structure) 1 comprising a 20 nm thickness of Al_{0.14}Ga_{0.86}N:Mg and 235 nm of GaN:Mg.

It will be noted that the current-voltage characteristics of the prototype are not degraded. Surprisingly, these characteristics are even better than those of the reference LED. This indicates that the converter does not add a significant resistance to the passage of the current.

The experimental results in FIGS. 9 and 10 relate to devices that are not according to the invention; however, they may be extrapolated to the case of a device according to the invention, of the type illustrated in FIG. 8.

By varying the thickness and the composition of the quantum wells of the converter 4 (the composition and size of the quantum dots, respectively) it is possible to obtain a fluorescent emission covering the entirety of the visible spectrum: blue (470 nm), green (530 nm), orange (590 nm) and red (650 nm). This is illustrated in FIG. 11. Combination of these colors should in principle allow any pure or mixed color, such as white, to be obtained.

1. A light-emitting device comprising a monolithic matrix of III-V nitrides, said matrix including at least a first stack of quantum wells or planes of quantum dots of group-Ill nitrides, a second stack of quantum wells or planes of quantum dots of III-V nitrides, and a region, referred to as the separating region, separating said two stacks of quantum wells or planes of quantum dots, and first and second electrodes arranged to allow an electric current to pass through said first stack of quantum wells or planes of quantum dots of group-III nitrides and also through at least a portion of said second stack of quantum wells or planes of quantum dots of group-III nitrides, wherein said first stack of quantum wells or planes of quantum dots of group-III nitrides is able to emit photons at at least a first wavelength via electrical injection of said electric current and said second stack of quantum wells or planes of quantum dots of group-III nitrides is able to emit photons at at least a second wavelength via optical pumping by said photons emitted by said first stack, said matrix being produced by epitaxial deposition, wherein said second stack of quantum wells or planes of quantum dots of III-V nitrides is n-doped, and in that wherein said separating region comprises a tunnel junction having an n⁺⁺-doped region arranged on the side of said second stack and a p⁺⁺-doped region arranged on the opposite side, and at least one p-doped layer arranged on that side of the separating region which is opposite said second stack, and in that wherein said first stack of quantum wells or planes of quantum dots of group-III nitrides is arranged between said separating region and at least one n-doped layer.

2. The device as claimed in claim 1, wherein said separating region has a thickness smaller than or equal to 1000 nm and preferably smaller than or equal to 500 nm.

3. The device as claimed in claim 1, wherein said first and second electrodes are arranged on either side of said monolithic matrix of group-III nitrides, whereby said electric current flows in a direction substantially perpendicular to said quantum wells or planes of quantum dots.

4. The device as claimed in claim 1, wherein said first and second wavelengths are chosen such that their combination gives white light.

5. The device as claimed in claim 1, wherein said matrix is deposited on a conductive substrate, said second stack being arranged on that side of said matrix which is opposite said substrate and said first stack being arranged between said substrate and said second stack.

6. A method for manufacturing a light-emitting device comprising a monolithic matrix of III-V nitrides, said matrix including at least a first stack of quantum wells or planes of quantum dots of group-III nitrides, a second stack of quantum wells or planes of quantum dots of III-V nitrides, and a region, referred to as the separating region, separating said two stacks of quantum wells or planes of quantum dots, and first and second electrodes arranged to allow an electric current to pass through said first stack of quantum wells or planes of quantum dots of group-III nitrides and also through at least a portion of said second stack of quantum wells or planes of quantum dots of group-III nitrides, wherein said first stack of quantum wells or planes of quantum dots of group-III nitrides is able to emit photons at at least a first wavelength via electrical injection of said electric current and said second stack of quantum wells or planes of quantum dots of group-III nitrides is able to emit photons at at least a second wavelength via optical pumping by said photons emitted by said first stack, said matrix being produced by epitaxial deposition, wherein said second stack of quantum wells or planes of quantum dots of III-V nitrides is n-doped, and in that said separating region comprises a tunnel junction having an n⁺⁺-doped region arranged on the side of said second stack and a p⁺⁺-doped region arranged on the opposite side, and at least one p-doped layer arranged on that side of the separating region which is opposite said second stack, and in that said first stack of quantum wells or planes of quantum dots of group-III nitrides is arranged between said separating region and at least one n-doped layer, the method comprising producing said monolithic matrix of group-III nitrides by epitaxial growth.

7. The method as claimed in claim 6, wherein said epitaxial growth is carried out entirely by metal organic chemical vapor deposition.
